(19) United States
(12) Patent Application Publication
(10) Pub. No.: US 2025/0248151 A1
(43) Pub. Date: Jul. 31, 2025

(54) SUBSTRATE PACKAGING STRUCTURE AND CAMERA MODULE HAVING THE SAME

(71) Applicant: TRIPLE WIN TECHNOLOGY(SHENZHEN) CO.LTD., Shenzhen (CN)

(72) Inventors: GWO-YAN HUANG, New Taipei (TW); YU-TENG JHENG, New Taipei (TW)

(21) Appl. No.: 18/640,415

(22) Filed: Apr. 19, 2024

(30) Foreign Application Priority Data
Jan. 29, 2024 (CN) 202420214221.8

(51) Int. Cl. H01L 27/146

(52) U.S. Cl. CPC H10F 39/804; H10F 39/811; H10F 39/8053; H10F 39/8063

(57) ABSTRACT

A substrate packaging structure which can reducing the probability of shape distortion or overflow of the packaging material is disclosed. The substrate packaging structure includes a substrate, an electronic component, and a packaging layer, and a limiting portion is arranged on the substrate. The limiting portion can guide the packaging material into the area enclosed by the limiting portion, reducing the probability of shape distortion or overflow caused by arbitrary diffusion of the packaging material. This allows for the formation of the packaging layer with an appropriate thickness and regular shape, thereby reducing the risk of visual defects. A camera module carrying the substrate packaging structure is also disclosed.

### FIELD

The subject matter herein generally relates to packaging technology, and more particularly, to a substrate packaging structure and a camera module having the substrate packaging structure.

### BACKGROUND

To protect the chip, insulating materials such as glue are generally used to encapsulate the chip. During the dispensing and coating process of the glue, factors including the viscosity coefficient of the glue, the flow rate of sprayed glue, the moving speed of the glue needle, the precision of the reciprocating motion of the dispensing equipment, and the surface smoothness of the substrate may affect the shape of the coated glue. For instance, distortion or scattering may happen on the coated glue. Additionally, width and thickness of the coated glue may not meet the specification requirements.

### BRIEF DESCRIPTION OF THE DRAWINGS

Implementations of the present disclosure will now be described, by way of embodiments only, with reference to the attached figures.

FIG. 1 is a diagrammatic view of an embodiment of a substrate according to the present disclosure.

FIG. 2 is a diagrammatic view of the substrate of FIG. 1 and an electronic component formed thereon.

FIG. 3 is a diagrammatic view of an embodiment of a substrate packaging structure obtained after a packaging layer is set on the structure of FIG. 2.

FIG. 4 is a cross-sectional view along IV-IV shown in FIG. 2.

FIG. 5 shows sectional views enlarging section A of FIG. 4 in different embodiments.

FIG. 6 is a sectional view of an embodiment of a portion of the substrate packaging structure of FIG. 3.

FIG. 7 is similar to FIG. 4, but showing the substrate packaging structure in another embodiment.

FIG. 8 shows sectional views enlarging section B of FIG. 7 in different embodiments.

FIG. 9 is a sectional view of another embodiment of a portion of the substrate packaging structure of FIG. 3.

FIG. 10 is a cross-sectional view of an embodiment of a cameral module according to the present disclosure.

### DETAILED DESCRIPTION

Unless otherwise defined, all technical and scientific terms used herein have the same meaning as commonly understood by persons skill in the art. The terms used herein are only for the purpose of describing specific embodiments, and not intended to limit the embodiments of the present application.

It should be noted that all directional indications (such as up, down, left, right, front, back, etc.) in the embodiments of the present application are only used to explain the relative positional relationship or movement between various components under a certain posture (as shown in the drawings). If the specific posture changes, the directional indication also changes accordingly.

It should be noted that when a component is referred to as being “fixed on” or “mounted on” another component, it may be directly on the other component or there may also be an intervening component. When a component is considered to be “set on” another component, it may be in direct contact with the other component or there may also be an intervening component. In the description of the present application, “plurality” means more than one unless expressly and specifically defined otherwise.

The embodiments of the present application are described here with reference to sectional views, which are schematic diagrams of idealized embodiments (and intermediate structures) of the present application. Therefore, the difference in the shape of the drawing due to the manufacturing process and/or tolerance is predictable. Accordingly, the embodiments of the present application should not be interpreted as limited to the specific shape of the area illustrated here, but should include, for example, the deviation of the shape due to manufacturing. The areas shown in the drawings are only schematic, and their shape is not used to illustrate the actual shape of the device, and is not used to limit the scope of the present disclosure.

Some embodiments of the present application will be described in detail below with reference to the drawings. The following embodiments and features of the embodiments may be combined with each other in the absence of conflict.

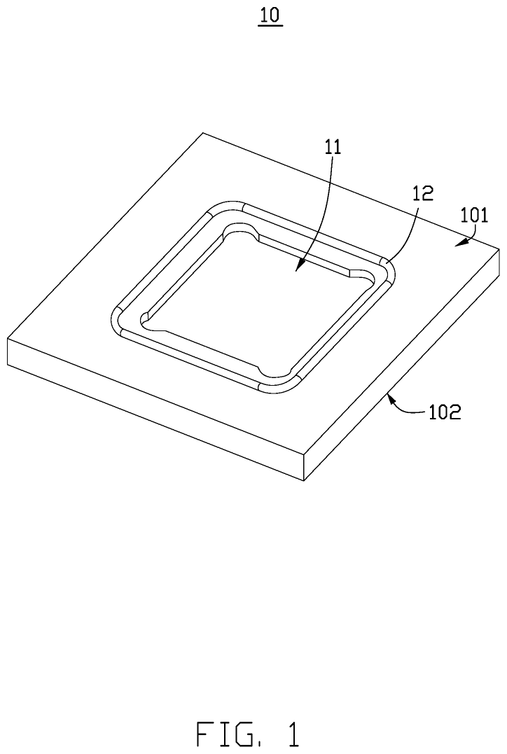

Referring to FIGS. 1 to 3, an embodiment of the present application provides a substrate packaging structure 100, which includes a substrate 10, an electronic component 20, and a packaging layer 30. The substrate 10 may be, but is not limited to, a printed circuit board (PCB), which may be a rigid printed circuit board, a flexible printed circuit board (FPC), or a flexible-rigid circuit board. The electronic component 20 may be, but is not limited to, a chip. The packaging layer 30 may be formed by curing a packaging material, which may be, but is not limited to, epoxy resin and/or polyimide.

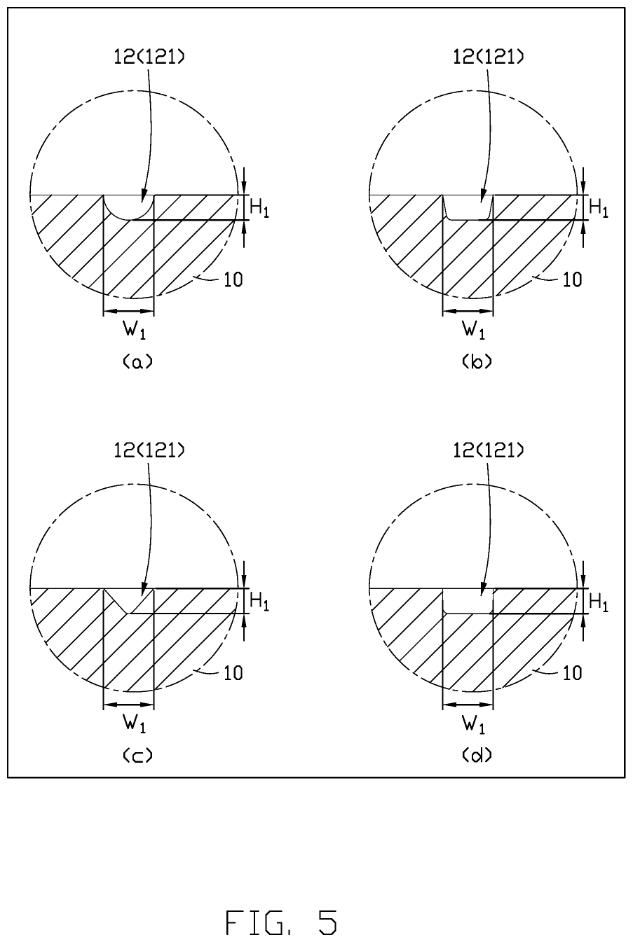

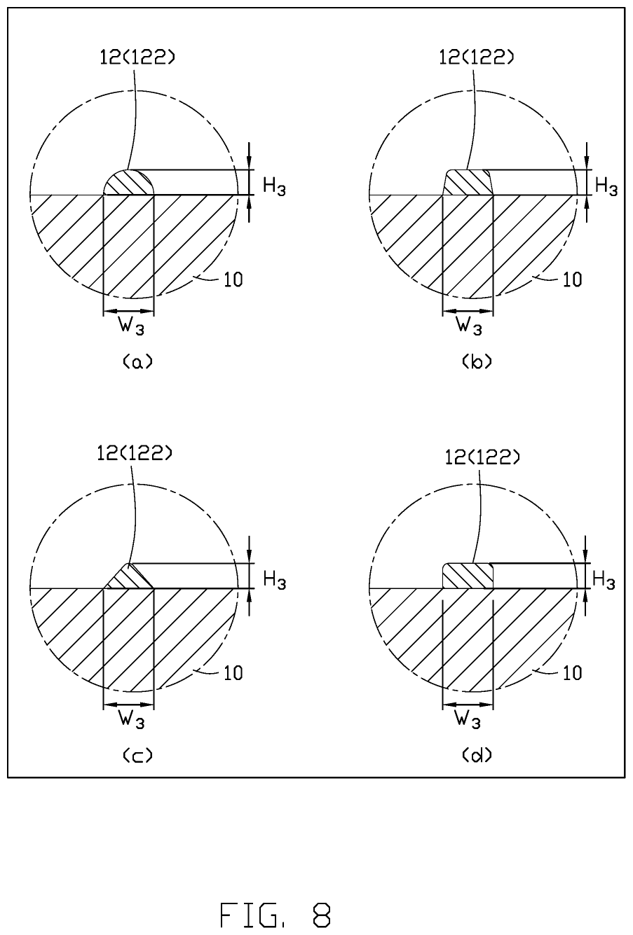

As shown in FIG. 1, the substrate 10 defines an installation groove 11, and a limiting portion 12 is disposed around the installation groove 11. The limiting portion 12 may be a groove 121 (referring to FIG. 5) or a protrusion 122 (referring to FIG. 8). The limiting portion 12 can guide the packaging material into the area enclosed by the limiting portion 12, thereby reducing the probability of shape distortion or overflow caused by arbitrary diffusion of the packaging material, thus reducing the quality risks caused by poor encapsulation on the substrate 10. The installation groove 11 is roughly located in the middle area of the substrate 10, and the orthogonal projection of the installation groove 11 on the substrate 10 is roughly rectangular.

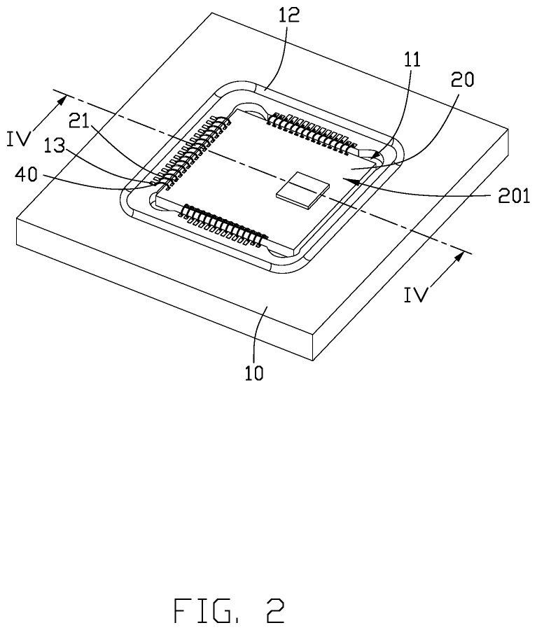

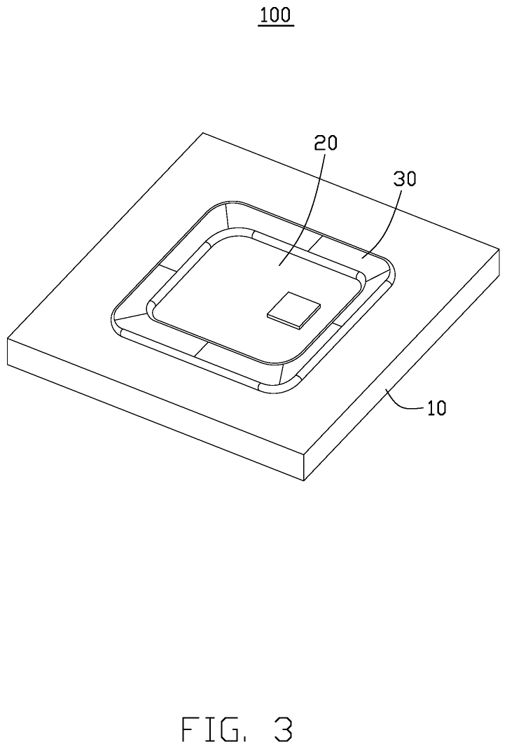

As shown in FIG. 2, the electronic component 20 is disposed in the installation groove 11. As shown in FIG. 3, the packaging layer 30 covers the electronic component 20 and the limiting portion 12. The packaging layer 30 covers a portion of the electronic component 20 near the limiting portion 12, while the remaining portion of the electronic component 20 can be exposed from the packaging layer 30. In some embodiments, the packaging layer 30 covers the entire surface of the limiting portion 12. In another embodiments, the packaging layer 30 covers only a portion of the surface of the limiting portion 12, while another portion of the surface of the limiting portion 12 is exposed from the packaging layer 30.

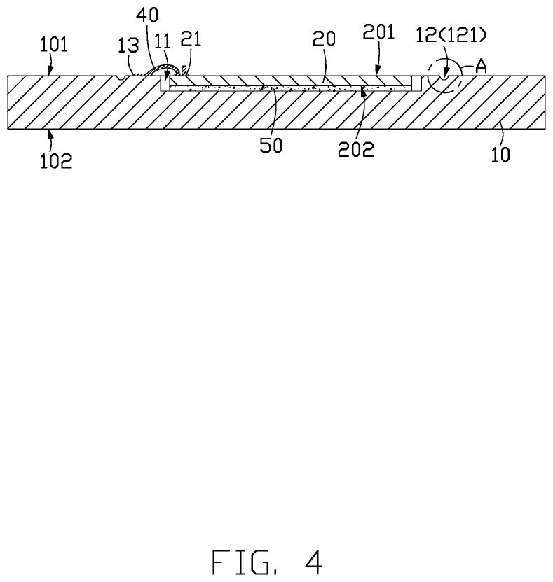

As shown in FIGS. 4 to 6, the limiting portion 12 is a groove 121. The depth of the groove 121 is denoted as H₁ (the depth of the groove 121 is the distance from the surface of the substrate 10 near the packaging layer 30 to the lowest point of the groove 121, wherein the distance is measured along the thickness direction of the substrate 10). The width of the groove 121 is denoted as W₁ (the width of the groove 121 is the value at the widest point of the groove 121 along the direction from the installation groove 11 to the limiting portion 12). The thickness of the packaging layer 30 is denoted as H₂ (the thickness of the packaging layer 30 is the distance from the highest point of the packaging layer 30 to the surface in contact with the substrate 10, wherein the distance is measured along the thickness direction of the substrate 10), and the width of the packaging layer 30 is denoted as W₂ (the width of the packaging layer 30 is the distance from the innermost point of the packaging layer 30 to its outermost edge, wherein the distance is measured along the width direction of the substrate 10). Wherein, H₁/1₂≥0.1, and W₁/H₁≥1. As such, the groove 121 has an appropriate depth and width, which can accommodate a suitable amount of the packaging material and guide the packaging material to the surface of the electronic component 20, forming the packaging layer 30 with an appropriate thickness.

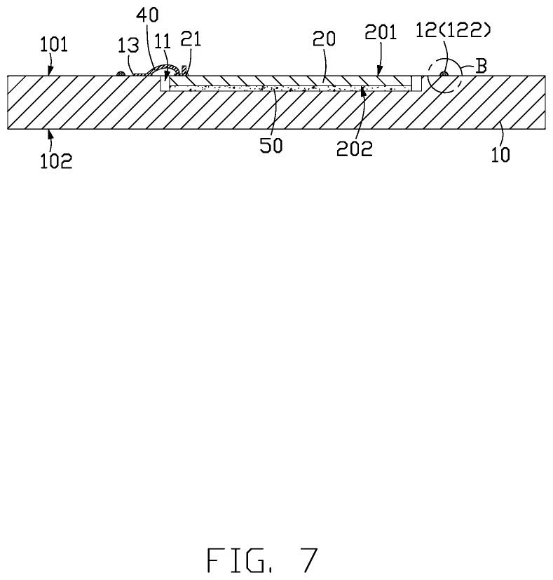

As shown in FIGS. 7 to 9, the limiting portion 12 is a protrusion 122. The height of the protrusion is denoted as H₃ (the height of the protrusion 122 is the distance from the highest point of the protrusion 122 to the surface in contact with the substrate 10, wherein the distance is measured along the thickness direction of the substrate 10), and the width of the protrusion 122 is denoted as W₃ (the width of the protrusion 122 is the value at the widest point of the protrusion 122 along the direction from the installation groove 11 to the limiting portion 12). Wherein, H₃/H₂≥0.2, W₃/H₃≤1. In this way, the protrusion 122 has an appropriate height and width, which can block the overflow of the packaging material and guide the packaging material to the surface of the electronic component 20, forming the packaging layer 30 with an appropriate thickness.

In some embodiments, as shown in FIG. 1, the substrate 10 includes a first surface 101 and a second surface 102 opposite to the first surface 101. The first surface 101 is partially recessed towards the second surface 102 to form the installation groove 11. The substrate packaging structure 100 further includes an adhesive layer 50 located inside the installation groove 11 to bond and fix the electronic component 20 to the installation groove 11. Furthermore, the adhesive layer 50 is arranged on the bottom wall of the installation groove 11. The adhesive layer 50 may include, but is not limited to, a silver paste.

In some embodiments, as shown in FIGS. 2 and 4, the electronic component 20 is a chip, which has an active surface 201 and a non-active surface 202 opposite to each other. Compared to the active surface 201, the non-active surface 202 is closer to the bottom wall of the installation groove 11. The active surface 201 is provided with a first pad 21, and the substrate 10 is provided with a second pad 13. The first pad 21 and the second pad 13 are electrically connected by a wire 40. The number of each of the first pad(s) 21 and second pad(s) 13 may be multiple, and each first pad 21 and each second pad 13 are electrically connected by a wire 40. Furthermore, the wire 40 may be, but is not limited to, a gold wire or a silver wire.

In some embodiments, as shown in FIGS. 4 and 5, when the limiting portion 12 is the groove 121, the groove 121 is formed by partially recessing the first surface 101 towards the second surface 102. In at least one embodiment, the groove 121 may be formed by, but is not limited to, laser cutting. The number of groove(s) 121 may be one or more, and multiple grooves 121 may be spaced apart around the installation groove 11.

In some embodiments, as shown in FIG. 5, the cross-sectional shape of the groove 121 may be semi-circular as shown in (a) of FIG. 5, trapezoidal as shown in (b) of FIG. 5, triangular as shown in (c) of FIG. 5, rectangular as shown in (d) of FIG. 5, water droplet shaped, stepped, strip shaped, or other regular or irregular shapes.

In some embodiments, the portion of the first surface 101 located between the groove 121 and the installation groove 11 may be roughened by atomization to further prevent the packaging material from spreading randomly.

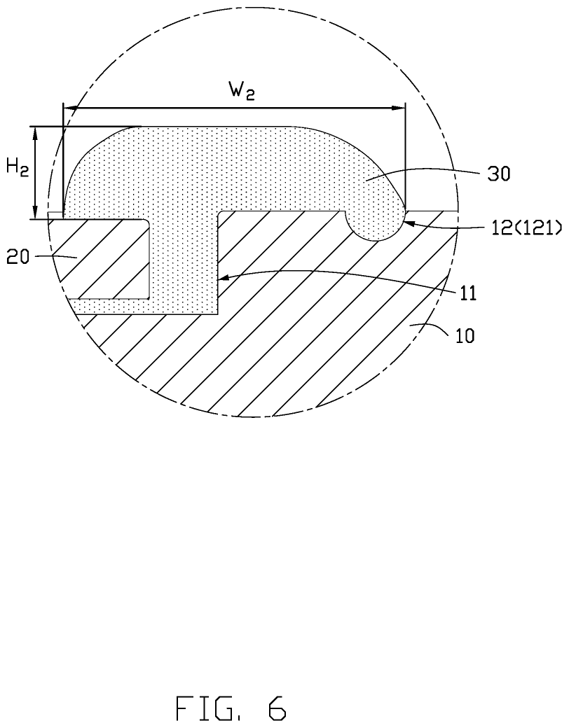

In some embodiments, as shown in FIG. 6, the packaging layer 30 not only fills the groove 121 and covers the surface of the electronic component 20, but also fills the gap between the electronic component 20 and the inner wall of the installation groove 11.

In some embodiments, as shown in FIGS. 7 and 8, when the limiting portion 12 is the protrusion 122, the protrusion 122 is formed by partially extending the first surface 101 in a direction away from the second surface 102. The height H₃ of the protrusion 122 is also the height of the protrusion 122 protruding from the first surface 101. In at least one embodiment, the protrusion 122 may be formed on the first surface 101 by, but is not limited to, printing, welding, or dispensing. The material of the protrusion 122 may be, but is not limited to, plastic, metal, or the like. The number of protrusion(s) 122 may be one or more, and multiple protrusions 122 may be spaced apart around the installation groove 11.

In some embodiments, as shown in FIG. 8, the cross-sectional shape of the protrusion 122 may be semi-circular as shown in (a) of FIG. 8, trapezoidal as shown in (b) of FIG. 8, triangular as shown in (c) of FIG. 8, rectangular as shown in (d) of FIG. 8, or other regular or irregular shapes.

In some embodiments, the portion of the first surface 101 located between the protrusion 122 and the installation groove 11 may be roughened by atomization to further prevent the packaging material from spreading randomly.

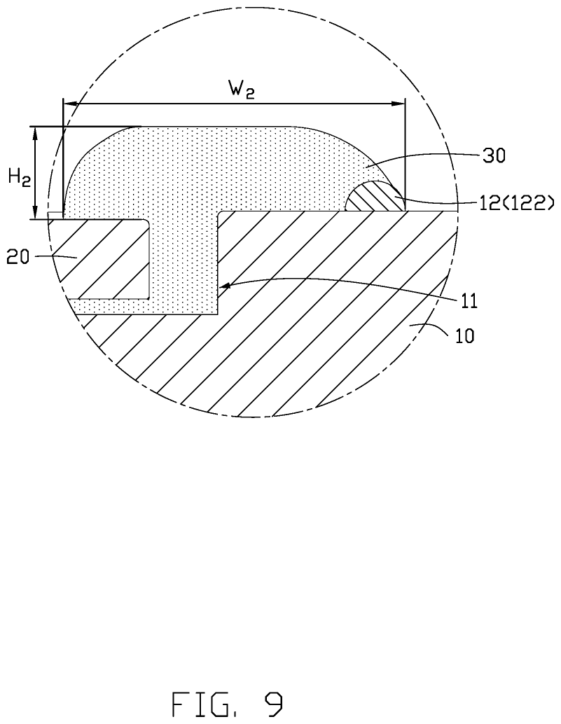

In some embodiments, as shown in FIG. 9, the packaging layer 30 not only covers the surface of the protrusion 122 and the electronic component 20, the packaging layer 30 also fills the gap between the electronic component 20 and the inner wall of the installation groove 11.

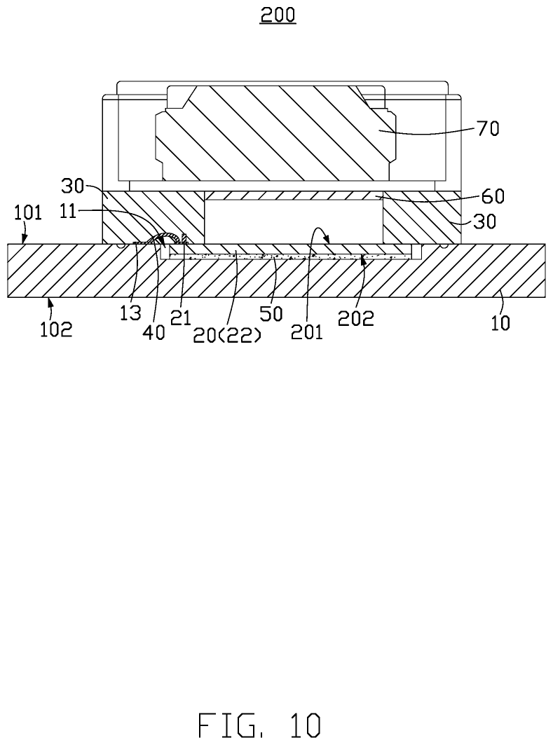

Referring to FIG. 10, the present application also provides a camera module 200 including the above-mentioned substrate packaging structure 100. In the camera module 200, the electronic component 20 is a photosensitive chip 22. In at least one embodiment, the photosensitive chip 22 may be a CMOS (Complementary Metal Oxide Semiconductor).

As shown in FIG. 10, the camera module 200 may also include a filter 60. The filter 60 is arranged on the packaging layer 30 and opposite to the photosensitive chip 22. In at least one embodiment, the filter 60 is opposite to the sensing area of the photosensitive chip 23. In some embodiments, the filter 60 is directly fixed on the packaging layer 30. After the packaging material is injected, the filter 60 is placed at a position on the packaging material and corresponds to the sensing area of the photosensitive chip 22. After curing the packaging material, the filter 60 is fixed on the packaging layer 30 formed by curing the packaging material. In other embodiments, the filter 60 may be fixed on the packaging layer 30 through a bonding layer. The filter 60 may be a blue glass filter only allowing permitted light to pass through, thereby ensuring imaging quality.

As shown in FIG. 10, the camera module 20 may also include a lens 70. The lens 70 is disposed on a surface of the packaging layer 30 away from the substrate 10. The filter 60 is disposed between the lens 40 and the photosensitive chip 22, and is located on an optical path of the lens 40.

The present application sets the limiting portion 12 on the substrate 10, and adjusts the relationship between the width and depth (or height) of the limiting portion 12, as well as the relationship between the depth (or height) of the limiting portion 12 and the thickness of the packaging layer 30, so that the limiting portion 12 can guide the packaging material into the area enclosed by the limiting portion 12, reducing the probability of shape distortion or overflow caused by arbitrary diffusion of the packaging material. Thus, the packaging layer 30 with an appropriate thickness and regular shape can be formed, thereby reducing the risk of visual defects in the substrate packaging structure 100.

The above descriptions are some specific embodiments of the present application, but the actual application process cannot be limited only to these embodiments. For those of ordinary skill in the art, other modifications and changes made according to the technical concept of the present application should all belong to the protection scope of the present application.

What is claimed is:

1. A substrate packaging structure, comprising:
a substrate defining an installation groove, wherein a limiting portion is arranged on the substrate and surrounds the installation groove, the limiting portion comprises a protrusion or a groove;
an electronic component arranged in the installation groove; and
a packaging layer covering the electronic component and the limiting portion,
wherein a depth of the groove is denoted as H₁, a width of the groove is denoted as W₁, a thickness of the packaging layer is denoted as H₂, H₁/H₂≥0.1, and W₁/H₁≥1; a height of the protrusion is denoted as H₃, a width of the protrusion is denoted as W₃, H₃/H₂≥0.2, and W₃/H₃≤1.

2. The substrate packaging structure of claim 1, wherein the substrate comprises a first surface and a second surface opposite to the first surface, and the first surface is partially recessed towards the second surface to form the installation groove.

3. The substrate packaging structure of claim 2, wherein the first surface is partially recessed towards the second surface to form the groove.

4. The substrate packaging structure of claim 2, wherein the protrusion is formed by partially extending the first surface in a direction away from the second surface.

5. The substrate packaging structure of claim 1, further comprising an adhesive layer located inside the installation groove, the adhesive layer fixing the electronic component in the installation groove.

6. The substrate packaging structure of claim 5, wherein the adhesive layer comprises a silver paste.

7. The substrate packaging structure of claim 1, wherein the electronic component is a chip, the chip has an active surface and a non-active surface opposite to the active surface, a first pad is arranged on the active surface, a second pad is arranged on the substrate, and the first pad and the second pad are electrically connected by a wire.

8. The substrate packaging structure of claim 7, wherein the wire is a gold wire or a silver wire.

9. The substrate packaging structure of claim 1, wherein the packaging layer comprises at least one of epoxy resin and polyimide.

10. A camera module comprising:
a substrate packaging structure, the substrate packaging structure comprising:
a substrate defining an installation groove, wherein a limiting portion is arranged on the substrate and surrounds the installation groove, the limiting portion comprises a protrusion or a groove;
a photosensitive chip arranged in the installation groove; and
a packaging layer covering the photosensitive chip and the limiting portion;
wherein a depth of the groove is denoted as H₁, a width of the groove is denoted as W₁, a thickness of the packaging layer is denoted as H₂, H₁/H₂≥0.1, and W₁/H₁≥1; a height of the protrusion is denoted as H₃, a width of the protrusion is denoted as W₃, H₃/H₂≥0.2, and W₃/H₃≤1.

11. The camera module of claim 10, further comprising a filter arranged on the packaging layer and arranged opposite to the photosensitive chip.

12. The camera module of claim 11, further comprising a lens arranged on a surface of the packaging layer away from the substrate, wherein the filter is located on an optical path of the lens.

13. The camera module of claim 10, wherein the substrate comprises a first surface and a second surface opposite to the first surface, and the first surface is partially recessed towards the second surface to form the installation groove.

14. The camera module of claim 13, wherein the first surface is partially recessed towards the second surface to form the groove.

15. The camera module of claim 13, wherein the protrusion is formed by partially extending the first surface in a direction away from the second surface.

16. The camera module of claim 10, wherein the substrate packaging structure further comprises an adhesive layer located inside the installation groove, the adhesive layer fixing the photosensitive chip in the installation groove.

17. The camera module of claim 16, wherein the adhesive layer comprises a silver paste.

18. The camera module of claim 10, wherein the photosensitive chip has an active surface and a non-active surface opposite to the active surface, a first pad is arranged on the active surface, a second pad is arranged on the substrate, and the first pad and the second pad are electrically connected by a wire.

19. The camera module of claim 18, wherein the wire is a gold wire or a silver wire.

20. The camera module of claim 10, wherein the packaging layer comprises at least one of epoxy resin and polyimide.
